(19) United States
(12) Patent Application Publication
(10) Pub. No.: US 2026/0255680 A1
(43) Pub. Date: Aug. 27, 2026

(54) SEMICONDUCTOR DEVICE AND DISPLAY DEVICE

(71) Applicant: SHARP KABUSHIKI KAISHA, Sakai City (JP)

(72) Inventor: Shogo Murashige, Sakai City (JP)

(21) Appl. No.: 19/550,605

(22) Filed: Feb. 26, 2026

(30) Foreign Application Priority Data
Feb. 27, 2025 (JP) 2025-029958

(51) Int. Cl. H10D 86/60; G02B 27/01; H10D 86/01; H10D 86/40

(52) U.S. Cl. CPC H10D 86/60; H10D 86/0212; H10D 86/411; H10D 86/441; G02B 27/017; G02B 2027/0178

(57) ABSTRACT

A semiconductor device includes: a first insulating film at least including silicon and nitrogen; a second insulating film disposed on an upper-layer side of the first insulating film and at least including silicon and oxygen; a semiconductor portion formed of part of a semiconductor film disposed on the upper-layer side of the second insulating film; a third insulating film disposed on the upper-layer side of the semiconductor film; and a first electrode formed of part of a first transparent electrode film disposed on the upper-layer side relative to the third insulating film, and disposed in such a manner as to at least partially overlap with part of the semiconductor portion in which a first contact hole that connects the semiconductor portion and the first electrode is provided at a position overlapping at least both the semiconductor portion and the first electrode in the third insulating film, and an opening is provided at a position overlapping at least part of the first contact hole in the second insulating film.

### CROSS-REFERENCE TO RELATED APPLICATIONS

This application claims the benefit of priority to Japanese Patent Application Number 2025-029958 filed on Feb. 27, 2025. The entire contents of the above-identified application are hereby incorporated by reference.

### BACKGROUND

### Technical Field

The technology disclosed herein relates to a semiconductor device and a display device in which an increase in contact resistance between a semiconductor portion and a first electrode is suppressed.

In the related art, a semiconductor device disclosed in JP 7488807 B is known as an example. JP 7488807 B describes an active matrix substrate that is used in a liquid crystal panel, as a semiconductor device. The active matrix substrate described in JP 7488807 B includes: a substrate; a pixel TFT that is supported by the substrate and provided corresponding to each of a plurality of pixel regions, and includes an oxide semiconductor layer; an organic insulating layer disposed above at least the oxide semiconductor layer of the pixel TFT; and an inorganic insulating layer disposed in contact with an upper face of the organic insulating layer on the organic insulating layer. The organic insulating layer and the inorganic insulating layer are provided with a plurality of dual-layer hole structure portions, each of the dual-layer hole structure portions includes a through-hole provided in the inorganic insulating layer and a bottomed hole provided in the organic insulating layer and located below the through-hole, and the through-hole is located on an inner side relative to an outer edge of the bottomed hole when viewed from a normal direction of the substrate.

### SUMMARY

In the active matrix substrate described in JP 7488807 B, a pixel electrode includes a first electrode layer (lower electrode layer), a second electrode layer (intermediate electrode layer), and a third electrode layer (upper electrode layer), each of which is formed of a transparent conductive material. The first electrode layer, the second electrode layer, and the third electrode layer are electrically connected to each other. Among these electrode layers, the first electrode layer functions as a connection electrode that electrically connects a drain contact region of the oxide semiconductor layer and the second electrode layer. However, the transparent electrode material constituting the first electrode layer contains oxygen. Because of this, when heat treatment is performed after the first electrode layer is formed in a manufacturing process, oxygen may diffuse from the first electrode layer into the drain contact region of the oxide semiconductor layer. When oxygen diffuses into the drain contact region, the resistance of the drain contact region increases, and as a result, there arises a possibility that the contact resistance between the drain contact region and the first electrode layer increases.

The technology described herein has been made based on the circumstances described above, and an object thereof is to suppress an increase in contact resistance between the semiconductor portion and the first electrode.
(1) A semiconductor device relating to the technology described in the present specification includes: a first insulating film at least including silicon and nitrogen; a second insulating film disposed on an upper-layer side of the first insulating film and at least including silicon and oxygen; a semiconductor portion formed of part of a semiconductor film disposed on the upper-layer side of the second insulating film; a third insulating film disposed on the upper-layer side of the semiconductor film; and a first electrode formed of part of a first transparent electrode film disposed on the upper-layer side relative to the third insulating film, and disposed in such a manner as to at least partially overlap with part of the semiconductor portion, wherein a first contact hole that connects the semiconductor portion and the first electrode is provided at a position overlapping at least both the semiconductor portion and the first electrode in the third insulating film, and an opening is provided at a position overlapping at least part of the first contact hole in the second insulating film.
(2) The semiconductor device may be provided with a recessed portion at a position in the first insulating film overlapping the opening, in addition to (1) described above.
(3) The semiconductor device may be such that, in addition to (1) or (2) described above, the opening may be disposed at a position overlapping both the semiconductor portion and the first electrode.
(4) The semiconductor device may be such that, in addition to (1) or (2) described above, the first electrode includes a portion that does not overlap the semiconductor portion, the first contact hole is also disposed at a position that overlaps the first electrode and does not overlap the semiconductor portion, and the opening is disposed at a position that overlaps the first electrode and does not overlap the semiconductor portion.
(5) In addition to any one of (1) to (4) described above, the semiconductor device may include: a fourth insulating film disposed on the upper-layer side of the semiconductor film and on a lower-layer side relative to the third insulating film, and disposed at a position overlapping with part of the semiconductor portion; a second electrode formed of part of a first metal film disposed on the upper-layer side of the fourth insulating film and on the lower-layer side of the third insulating film, and disposed at a position overlapping with part of the fourth insulating film and part of the semiconductor portion; a third electrode formed of part of a second metal film disposed on the upper-layer side of the third insulating film and on the lower-layer side relative to the first transparent electrode film, and disposed at a position overlapping with part of the semiconductor portion; a fifth insulating film disposed on the upper-layer side of the second metal film and on the lower-layer side of the first transparent electrode film; a sixth insulating film disposed on the upper-layer side of the first transparent electrode film; and a fourth electrode formed of part of a second transparent electrode film disposed on the upper-layer side of the sixth insulating film, and disposed partially overlapping the first electrode, wherein a second contact hole connecting the semiconductor portion and the third electrode may be provided at a position in the third insulating film overlapping both the semiconductor portion and the third electrode, a third contact hole connecting the first electrode and the fourth electrode may be provided at a position in the sixth insulating film overlapping both the first electrode and the fourth electrode, and the first contact hole may be provided passing through the third insulating film and the fifth insulating film.
(6) A display device relating to the technology described herein includes the semiconductor device described in any one of (1) to (5) discussed above, and a counter substrate that is disposed facing the semiconductor device.

According to the technology described herein, an increase in contact resistance between the semiconductor portion and the first electrode can be suppressed.

### BRIEF DESCRIPTION OF DRAWINGS

The disclosure will be described with reference to the accompanying drawings, wherein like numbers reference like elements.

FIG. 1 is a schematic perspective view illustrating a state in which a head-mounted display according to a first embodiment is worn on the head by a user.

FIG. 2 is a schematic side view illustrating an optical relationship between a liquid crystal display device and a lens unit provided in a head-mounted device included in the head-mounted display according to the first embodiment, and an eyeball of the user.

FIG. 3 is a schematic plan view illustrating a liquid crystal panel and a flexible substrate provided in the liquid crystal display device according to the first embodiment.

FIG. 4 is a schematic cross-sectional view of the liquid crystal panel according to the first embodiment.

FIG. 5 is a plan view illustrating a pixel arrangement in a display region of an array substrate provided in the liquid crystal panel according to the first embodiment.

FIG. 6 is a cross-sectional view of the array substrate according to the first embodiment taken along line vi-vi in FIG. 5.

FIG. 7 is a cross-sectional view similar to that in FIG. 6, illustrating a state before a first insulating film and a second insulating film are etched via a first photoresist film in a first step included in an array substrate manufacturing step according to the first embodiment.

FIG. 8 is a cross-sectional view similar to that in FIG. 6, illustrating a state where the first insulating film and the second insulating film are etched via the first photoresist film in the first step included in the array substrate manufacturing step according to the first embodiment.

FIG. 9 is a cross-sectional view similar to that in FIG. 6, illustrating a state before a semiconductor film is etched via a second photoresist film in a second step included in the array substrate manufacturing step according to the first embodiment.

FIG. 10 is a cross-sectional view similar to that in FIG. 6, illustrating a state where the semiconductor film is etched via the second photoresist film in the second step included in the array substrate manufacturing step according to the first embodiment.

FIG. 11 is a cross-sectional view similar to that in FIG. 6, illustrating a state before a first interlayer insulating film and a second interlayer insulating film are etched via a third photoresist film in a seventh step included in the array substrate manufacturing step according to the first embodiment.

FIG. 12 is a cross-sectional view similar to that in FIG. 6, illustrating a state where the first interlayer insulating film and the second interlayer insulating film are etched via the third photoresist film in the seventh step included in the array substrate manufacturing step according to the first embodiment.

FIG. 13 is a cross-sectional view similar to that in FIG. 6, illustrating a state before a first transparent electrode film is etched via a fourth photoresist film in an eighth step included in the array substrate manufacturing step according to the first embodiment.

FIG. 14 is a cross-sectional view similar to that in FIG. 6, illustrating a state where the first transparent electrode film is etched via the fourth photoresist film in the eighth step included in the array substrate manufacturing step according to the first embodiment.

FIG. 15 is a plan view illustrating a pixel arrangement in a display region of an array substrate according to a second embodiment.

FIG. 16 is a cross-sectional view of the array substrate according to the second embodiment taken along line xvi-xvi in FIG. 15.

FIG. 17 is a cross-sectional view similar to that in FIG. 16, illustrating a state before a first insulating film, a second insulating film, a first interlayer insulating film, and a second interlayer insulating film are etched via a third photoresist film in a seventh step included in an array substrate manufacturing step according to the second embodiment.

FIG. 18 is a cross-sectional view similar to that in FIG. 16, illustrating a state where the first insulating film, the second insulating film, the first interlayer insulating film, and the second interlayer insulating film are etched via the third photoresist film in the seventh step included in the array substrate manufacturing step according to the second embodiment.

FIG. 19 is a cross-sectional view similar to that in FIG. 16, illustrating a state before a first transparent electrode film is etched via a fourth photoresist film in an eighth step included in the array substrate manufacturing step according to the second embodiment.

FIG. 20 is a cross-sectional view similar to that in FIG. 16, illustrating a state where the first transparent electrode film is etched via the fourth photoresist film in the eighth step included in the array substrate manufacturing step according to the second embodiment.

### DESCRIPTION OF EMBODIMENTS

### First Embodiment

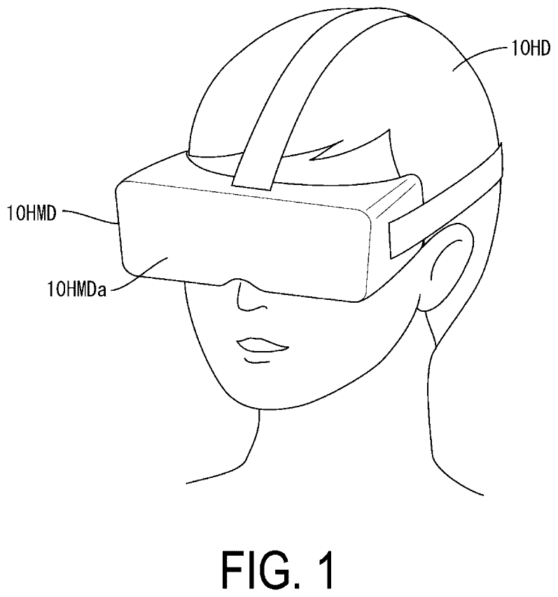

A first embodiment will be described with reference to FIG. 1 to FIG. 14. In the present embodiment, a goggle-type head-mounted display (Head-Mounted Display (HMD)) 10HMD and a liquid crystal display device (display device) 10 used for the head-mounted display are exemplified. Note that some drawings illustrate an X-axis, a Y-axis, and a Z-axis, and directions of these axes are drawn so as to be common in all the drawings.

The appearance of the goggle-type head-mounted display 10HMD will be described with reference to FIG. 1. As illustrated in FIG. 1, the head-mounted display 10HMD includes a head-mounted device 10HMDa mounted on a head 10HD of a user. The head-mounted device 10HMDa surrounds both eyes of the user.

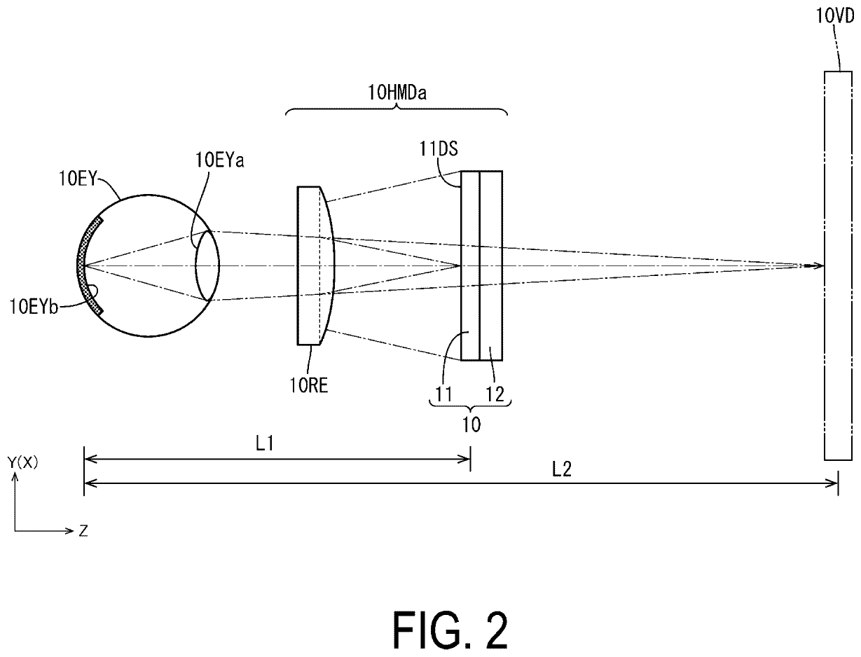

A configuration of the head-mounted device 10HMDa will be described with reference to FIG. 2. As illustrated in FIG. 2, the head-mounted device 10HMDa incorporates at least the liquid crystal display device 10 configured to display an image and a lens unit 10RE configured to focus the image displayed on the liquid crystal display device 10 on an eyeball 10EY of the user. The liquid crystal display device 10 includes at least a liquid crystal panel (display device) 11 and a backlight device (illumination device) 12 configured to irradiate the liquid crystal panel 11 with light. A main surface of the liquid crystal panel 11 on the lens unit 10RE side is a display surface 11DS that displays the image. The lens unit 10RE is interposed between the liquid crystal display device 10 and the eyeball 10EY of the user. The lens unit 10RE imparts a refracting action to light. By adjusting a focal length of the lens unit 10RE, the user can recognize that an image focused on a retina 10EYb through a crystalline lens 10EYa of the eyeball 10EY is displayed on a virtual display 10VD that is apparently present at a position of a distance L2 from the eyeball 10EY. This distance L2 is much larger than an actual distance L1 from the eyeball 10EY to the liquid crystal display device 10. As a result, the user can visually recognize an enlarged image that is a virtual image displayed on the virtual display 10VD having a screen size (for example, from about several tens of inches to about several hundreds of inches) much larger than a screen size (for example, from about several tenths of an inch to about several inches) of the liquid crystal display device 10.

By mounting one liquid crystal display device 10 on the head-mounted device 10HMDa, an image for the right eye and an image for the left eye can be displayed on the liquid crystal display device 10. Alternatively, by mounting two liquid crystal display devices 10 on the head-mounted device 10HMDa, the image for the right eye and the image for the left eye may be displayed on one of the liquid crystal display devices 10 and on the other of the liquid crystal display devices 10, respectively. The head-mounted device 10HMDa may be provided with earphones or the like that are put to the ears of the user and emit a sound.

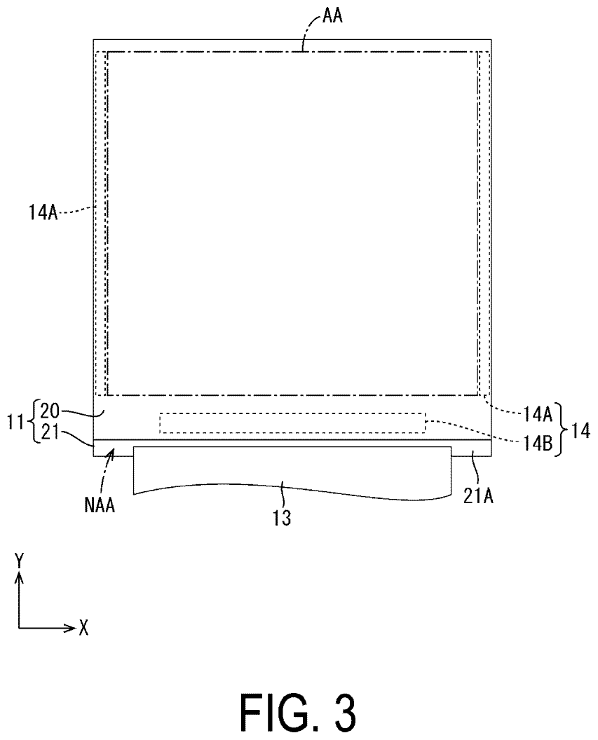

A configuration of the liquid crystal panel 11 included in the liquid crystal display device 10 will be described with reference to FIG. 3 and the like. Note that the configuration of the backlight device 12 is as known, and includes, for example, a light source such as an LED, an optical member that converts light from the light source into planar light by applying an optical effect to the light from the light source, and the like. As illustrated in FIG. 3, the liquid crystal panel 11 has a rectangular shape as a whole in a plan view. A center-side portion of the screen of the liquid crystal panel 11 is a display region AA in which an image is displayed. A frame-shaped outer peripheral portion surrounding the display region AA of the screen of the liquid crystal panel 11 is a non-display region NAA in which no image is displayed. A range surrounded by an alternating dotted-dashed line in FIG. 3 is the display region AA. The liquid crystal panel 11 according to the present embodiment is used in the head-mounted display 10HMD described above and thus has an extremely high resolution, with a pixel density thereof being, for example, about 1000 ppi or more.

As illustrated in FIG. 3, the liquid crystal panel 11 is formed by bonding a pair of substrates 20 and 21 together. Of the pair of substrates 20 and 21, one disposed on a front side is a counter substrate (CF substrate) 20, and the other one disposed on a back side is an array substrate (semiconductor device, active matrix substrate) 21. The counter substrate 20 and the array substrate 21 are each formed by layering various films on an inner face side of a respective one of glass substrates 20GS and 21GS that are substantially transparent and have excellent light-transmittance. The substrates 20GS and 21GS contain, for example, alkali-free glass as a main material. The array substrate 21 is larger than the counter substrate 20, and part of the array substrate 21 protrudes laterally relative to the counter substrate 20. A flexible substrate 13 is mounted on a protruding portion 21A of the array substrate 21. The flexible substrate 13 has a configuration in which a plurality of wiring line patterns are formed on a base material having insulating properties and flexibility. One end side of the flexible substrate 13 is connected to the array substrate 21, and the other end side thereof is connected to an external control substrate (signal supply source). Various signals supplied from the control substrate are transmitted to the liquid crystal panel 11 via the flexible substrate 13.

As illustrated in FIG. 3, a circuit portion (peripheral circuit portion) 14 is provided in the non-display region NAA of the liquid crystal panel 11. The circuit portion 14 includes a first circuit portion 14A and a second circuit portion 14B. A pair of the first circuit portions 14A are disposed sandwiching the display region AA from both sides in the X-axis direction. The first circuit portion 14A is provided in a belt-shaped range extending along the Y-axis direction. The first circuit portion 14A is configured to supply a scanning signal to a gate wiring line 25 described below, and is monolithically provided on the array substrate 21. The first circuit portion 14A is a Gate Driver Monolithic (GDM) circuit. The first circuit portion 14A includes a shift register circuit configured to output the scanning signal at a predetermined timing, a buffer circuit for amplifying the scanning signal, and the like. The second circuit portion 14B is disposed at a position interposed between the display region AA and the flexible substrate 13 in the Y-axis direction. The second circuit portion 14B is provided in a belt-shaped range extending along the X-axis direction. The second circuit portion 14B is configured to supply an image signal (data signal) to each of source wiring lines 26, which will be described below, and monolithically provided on the array substrate 21. The second circuit portion 14B includes a Source Shared Driving (SSD) circuit and the like. The second circuit portion 14B has a switching function of distributing an image signal supplied by the flexible substrate 13 to each source wiring line 26 or the like. Similarly to the first circuit portion 14A, the second circuit portion 14B may overlap the counter substrate 20.

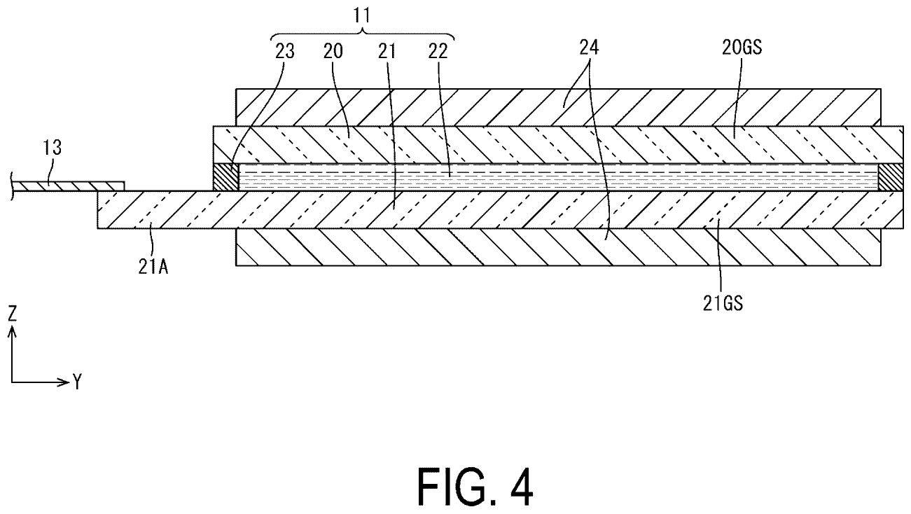

Next, a schematic cross-sectional configuration of the liquid crystal panel 11 will be described with reference to FIG. 4. As illustrated in FIG. 4, the pair of substrates 20 and 21 are disposed to face each other at an interval in the Z-axis direction that is the normal direction of main surfaces of the substrates 20 and 21. At least a liquid crystal layer 22 and a sealing portion 23 sealing the liquid crystal layer 22 are each interposed between the pair of substrates 20 and 21. The liquid crystal layer 22 contains liquid crystal molecules that serve as a substance having optical characteristics that change according to an applied electrical field. The sealing portion 23 has a rectangular frame-like shape (endless ring shape) as a whole in a plan view, and surrounds the entire periphery of the liquid crystal layer 22 in the non-display region NAA. A gap (cell gap) corresponding to a thickness of the liquid crystal layer 22 is maintained by the sealing portion 23. Note that each of polarizers 24 is bonded to a respective one of outer face sides of the pair of substrates 20 and 21.

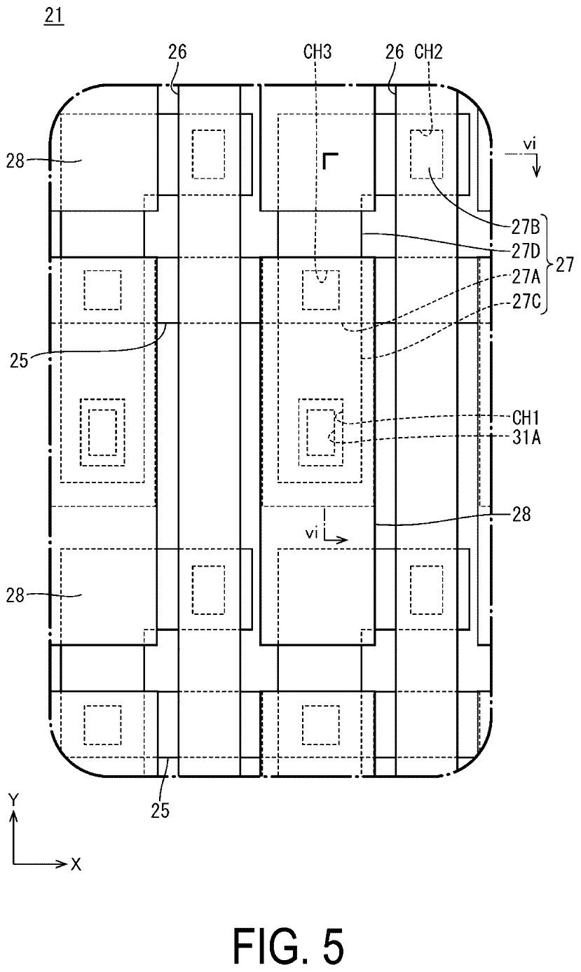

An overview of a pixel arrangement in the display region AA of the array substrate 21 will now be described with reference to FIG. 5. A plurality of gate wiring lines (scanning wiring lines, first wiring lines) 25 and a plurality of source wiring lines (image wiring lines, second wiring lines) 26 are disposed on an inner face side of the display region AA of the array substrate 21 as illustrated in FIG. 5. The plurality of gate wiring lines 25 extend along the X-axis direction (first direction) across the display region AA, and are disposed side by side with a space therebetween in the Y-axis direction. The scanning signal lines output from the first circuit portion 14A described above are supplied to the plurality of gate wiring lines 25. The source wiring lines 26 extend along the Y-axis direction (a second direction intersecting the first direction) across the display region AA and intersect the gate wiring lines 25. The plurality of source wiring lines 26 are disposed at intervals in the X-axis direction. Thus, the plurality of gate wiring lines 25 and the plurality of source wiring lines 26 form a lattice pattern in a plan view. The image signals output from the second circuit portion 14B are distributed to the source wiring lines 26.

As illustrated in FIG. 5, a TFT (switching element) 27 and a pixel electrode (fourth electrode) 28 are provided near an intersection of the gate wiring line 25 and the source wiring line 26. A plurality of the TFTs 27 and a plurality of the pixel electrodes 28 are disposed regularly along the X-axis direction and the Y-axis direction. The TFT 27 at least includes a gate electrode (second electrode) 27A, a source electrode (third electrode) 27B, a drain electrode (first electrode) 27C, and a semiconductor portion 27D. The gate electrode 27A is constituted of part of the gate wiring line 25. The source electrode 27B is constituted of part of the source wiring line 26. The drain electrode 27C is connected to the pixel electrode 28. The semiconductor portion 27D is connected to both the source electrode 27B and the drain electrode 27C, and disposed overlapping the gate electrode 27A at an interval in the Z-axis direction. The TFT 27 is driven based on the scanning signal supplied to the gate electrode 27A by the gate wiring line 25. The scanning signal has a potential higher than a threshold voltage of the TFT 27. Then, a channel region is generated in the semiconductor portion 27D, so that charge can move between the source electrode 27B and the drain electrode 27C through the channel region. Thus, a potential in accordance with an image signal (data signal) supplied to the source electrode 27B by the source wiring line 26 is supplied to the drain electrode 27C through the semiconductor portion 27D. As a result, the pixel electrode 28 is charged to the potential in accordance with the image signal. A detailed configuration of the TFT 27 and the pixel electrode 28 will be described below.

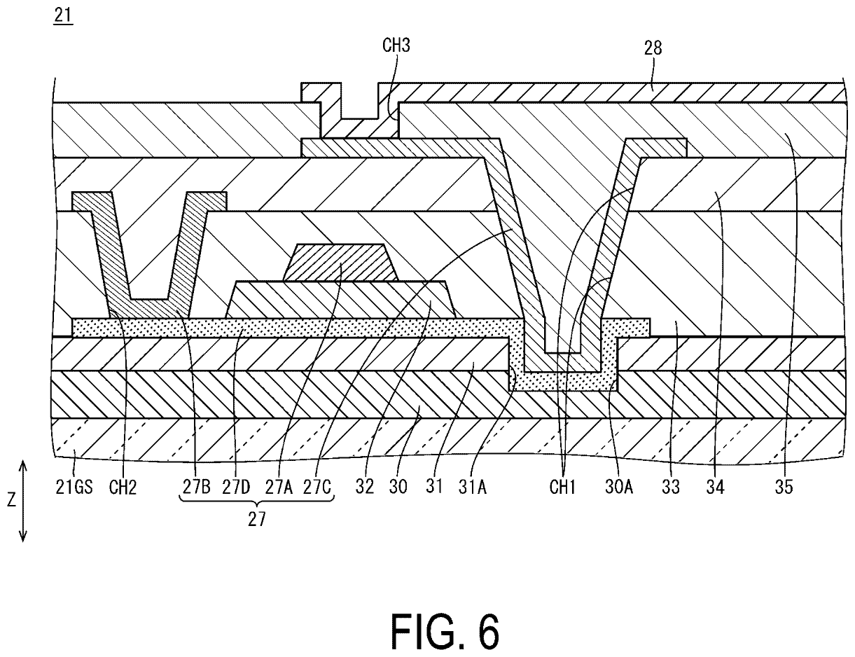

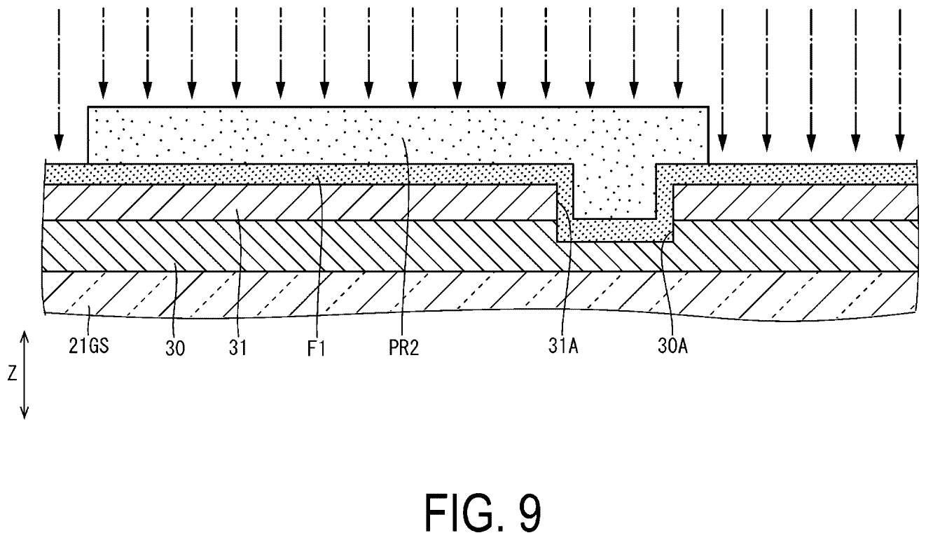

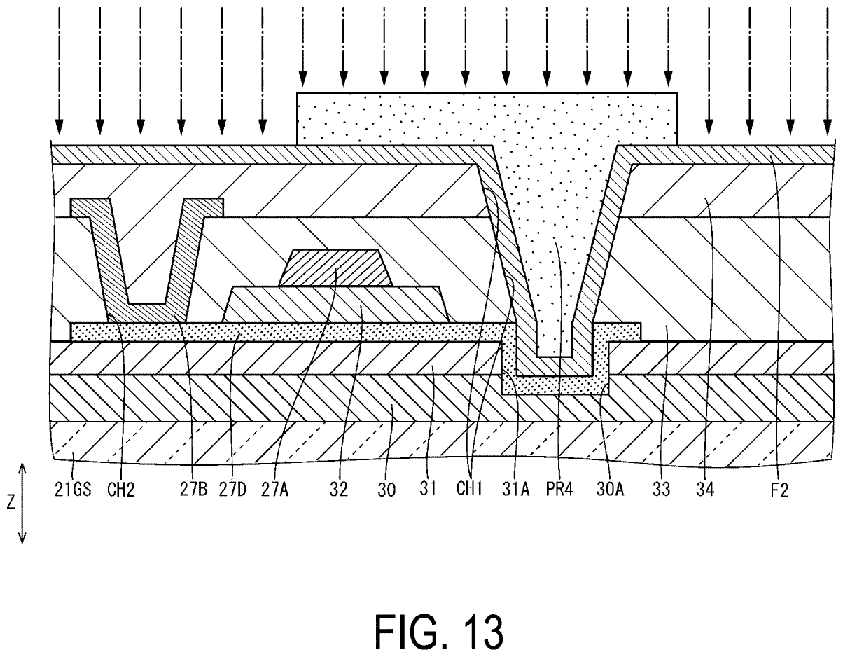

Subsequently, the various films layered on the glass substrate 21GS of the array substrate 21 will be described in detail with reference to FIG. 6. As illustrated in FIG. 6, a first insulating film 30, a second insulating film 31, a semiconductor film F1, a gate insulating film (fourth insulating film) 32, a first metal film, a first interlayer insulating film (third insulating film) 33, a second metal film, a second interlayer insulating film (fifth insulating film) 34, a first transparent electrode film F2, a third interlayer insulating film (sixth insulating film) 35, and a second transparent electrode film are at least layered and formed in this order from the lower-layer side (from the glass substrate 21GS side) on the glass substrate 21GS of the array substrate 21 (see FIG. 9 regarding the semiconductor film F1, see FIG. 13 regarding the first transparent electrode film F2). Note that an alignment film (not illustrated) for aligning the liquid crystal molecules contained in the liquid crystal layer 22 is provided on the innermost face (uppermost layer) of the array substrate 21 facing the liquid crystal layer 22.

The first metal film and the second metal film are both single-layer films made of one type of metal material, or layered films or alloys made of different types of metal materials, and thus have electrical conductivity. As illustrated in FIG. 6, the first metal film constitutes the gate wiring line 25, the gate electrode 27A, and the like. The second metal film constitutes the source wiring line 26, the source electrode 27B, and the like. The first transparent electrode film F2 and the second transparent electrode film are made of a transparent electrode material such as indium tin oxide (ITO) or indium zinc oxide (IZO) (see FIG. 13). The first transparent electrode film F2 constitutes the drain electrode 27C and the like. The second transparent electrode film constitutes the pixel electrode 28 and the like.

The semiconductor film F1 is made of an oxide semiconductor material (see FIG. 9). Specifically, the semiconductor film F1 is made of an oxide thin film which is a type of oxide semiconductor including indium (In), gallium (Ga), and zinc (Zn), for example. The oxide thin film containing indium (In), gallium (Ga), and zinc (Zn) is amorphous or crystalline. The oxide semiconductor material of the semiconductor film F1 has characteristics exhibiting a higher resistance value in a state in which no voltage is applied (off state) than a silicon semiconductor material. Further, the oxide semiconductor material of the semiconductor film F1 has higher electron mobility than that of an amorphous silicon semiconductor material.

The semiconductor film F1 constitutes the semiconductor portion 27D of the TFT 27 and the like, as illustrated in FIG. 6. The semiconductor portion 27D constituted of part of the semiconductor film F1 is partially made to be conductive (to have low resistance). Specifically, a portion of the semiconductor portion 27D overlapping the gate electrode 27A (gate wiring line 25) is a portion that is not made conductive (non-conductivity inducing portion, non-low-resistance inducing portion), and a portion thereof not overlapping the gate electrode 27A is a portion that is made conductive (conductivity inducing portion, low-resistance inducing portion). In the non-conductivity inducing portion of the semiconductor portion 27D, charge can move only under a specific condition (when a scanning signal is supplied to the gate electrode 27A). That is, the non-conductivity inducing portion functions as a channel region under the specific condition. On the other hand, the conductivity inducing portion of the semiconductor portion 27D functions as a conductor where charge can always move.

Each of the first insulating film 30, the second insulating film 31, the gate insulating film 32, the first interlayer insulating film 33, and the second interlayer insulating film 34 is made of an inorganic material (inorganic resin material). The first insulating film 30 is made of silicon nitride (SiNₓ) and contains at least silicon and nitrogen. In the present embodiment, the first insulating film 30 made of SiNₓ contains hydrogen (H₂). The reason why the first insulating film 30 contains H₂ is that a hydride gas such as silane gas (SiH₄), tetraethyl orthosilicate (TEOS), or NH3 is contained as a material to be used for film formation. As illustrated in FIG. 6, the first insulating film 30 is directly layered on the glass substrate 21GS and located on the lower-layer side of the first metal film. The second insulating film 31 is made of silicon oxide or silicon oxide substance (SiO₂) and contains at least silicon and oxygen. The second insulating film 31 is located on the upper-layer side of the first insulating film 30 and on the lower-layer side of the semiconductor film F1.

The gate insulating film 32 is made of SiO₂ and contains at least silicon and oxygen. As illustrated in FIG. 6, the gate insulating film 32 is located on the upper-layer side of the semiconductor film F1 and on the lower-layer side of the first metal film. The gate insulating film 32 has an island shape in a plan view, and is disposed at a position overlapping the semiconductor portion 27D of the TFT 27. The gate insulating film 32 is interposed between the semiconductor portion 27D and the gate electrode 27A to keep them insulated from each other. The first interlayer insulating film 33 is made of SiO₂ and contains at least silicon and oxygen. The first interlayer insulating film 33 is located on the upper-layer side of the first metal film and on the lower-layer side of the second metal film. The first interlayer insulating film 33 is interposed between the gate wiring line 25 and the source wiring line 26 to keep them insulated from each other. The second interlayer insulating film 34 is made of SiO₂, SiNₓ, or the like. The second interlayer insulating film 34 is located on the upper-layer side of the second metal film and on the lower-layer side of the first transparent electrode film F2. The second interlayer insulating film 34 is interposed between the source wiring line 26 and the drain electrode 27C to keep them insulated from each other. The third interlayer insulating film 35 is made of an inorganic material or an organic material (organic resin material). When the third interlayer insulating film 35 is made of an inorganic material, the third interlayer insulating film 35 is made of SiO₂, SiNₓ, or the like. When the third interlayer insulating film 35 is made of an organic material, the third interlayer insulating film 35 is made of an acrylic resin (PMMA) or the like. The third interlayer insulating film 35 is located on the upper-layer side of the first transparent electrode film F2 and on the lower-layer side of the second transparent electrode film. The third interlayer insulating film 35 is interposed between the drain electrode 27C and the pixel electrode 28.

When a display mode of the liquid crystal panel 11 is, for example, a fringe field switching (FFS) mode or the like, a fourth interlayer insulating film on the upper-layer side of the second transparent electrode film and a third transparent electrode film on the upper-layer side of the fourth interlayer insulating film are layered and formed on the array substrate 21. In this case, the third transparent electrode film is set at a common potential and constitutes a common electrode overlapping all the pixel electrodes 28. On the other hand, when the display mode of the liquid crystal panel 11 is, for example, a vertical alignment (VA) mode, a twisted nematic (TN) mode, or the like, a counter electrode overlapping all the pixel electrodes 28 is provided on the counter substrate 20.

Hereinafter, a configuration of the TFT 27 and the pixel electrode 28 will be described in detail. As illustrated in FIG. 6, the TFT 27 according to the present embodiment is a so-called top gate type in which the gate electrode 27A is located on the upper-layer side relative to the semiconductor portion 27D with the gate insulating film 32 interposed therebetween. As illustrated in FIG. 5, the semiconductor portion 27D of the TFT 27 has an L shape as a whole in a plan view, and includes a portion extending along the X-axis direction and a portion extending along the Y-axis direction. Of the portion extending along the X-axis direction of the semiconductor portion 27D, an end portion on the opposite side to the portion extending along the Y-axis direction (the right side in FIG. 5) overlaps the source wiring line 26. A portion of the source wiring line 26 overlapping the semiconductor portion 27D constitutes the source electrode 27B. Of the portion extending along the Y-axis direction in the semiconductor portion 27D, one end portion (the upper side in FIG. 5) is continuous with the portion extending along the X-axis direction, and an intermediate portion that extends to the other end portion (the lower side in FIG. 5) intersects the gate wiring line 25. A portion of the gate wiring line 25 intersecting (overlapping) the semiconductor portion 27D constitutes the gate electrode 27A.

As illustrated in FIG. 5, the drain electrode 27C extends along the Y-axis direction and has an elongated rectangular shape in a plan view. The drain electrode 27C is wider than the portion of the semiconductor portion 27D extending along the Y-axis direction. The width dimension of the drain electrodes 27C is slightly smaller than a distance between two adjacent source wiring lines 26 in the X-axis direction. The drain electrode 27C is disposed such that one end portion thereof (the upper side in FIG. 5) overlaps the gate wiring line 25, and the other end portion thereof (the lower side in FIG. 5) extends to a position beyond the portion of the semiconductor portion 27D extending along the Y-axis direction. The drain electrode 27C overlaps with most of the portion of the semiconductor portion 27D extending along the Y-axis direction (the portion excluding the end portion continuous with the portion extending along the X-axis direction). The drain electrode 27C is connected to the other end portion of the portion of the semiconductor portion 27D extending along the Y-axis direction. As described above, the L-shaped semiconductor portion 27D in a plan view has both the end portions connected to the source electrode 27B and the drain electrode 27C, respectively, and the intermediate portion between those connecting portions overlaps the gate electrode 27A.

As illustrated in FIG. 6, the pixel electrode 28 extends along the Y-axis direction and has an elongated rectangular shape in a plan view. The pixel electrode 28 has substantially the same width dimension as the drain electrode 27C. The pixel electrode 28 is disposed such that one end portion thereof (the upper side in FIG. 5) overlaps the gate wiring line 25, while the other end portion thereof (the lower side in FIG. 5) extends to the vicinity of the gate wiring line 25 adjacent at the lower side of FIG. 5 in the Y-axis direction at a position beyond the drain electrode 27C. That is, the pixel electrode 28 has a larger length dimension than the drain electrode 27C, and overlaps substantially the entire region of the drain electrodes 27C. As described above, although the drain electrode 27C overlaps with most of the pixel electrode 28, it is constituted by the first transparent electrode film F2, which transmits light. Accordingly, compared to a case in which the drain electrode 27C is formed of part of a metal film, it is possible to secure a sufficiently large quantity of light that is transmitted through the pixel electrode 28. That is, since a pixel aperture ratio can be improved, the disclosure is particularly useful when the resolution of the liquid crystal panel 11 is high. The other end portion of the pixel electrode 28 overlaps an L-shaped portion located between a portion connected to the source electrode 27B and a portion intersecting the gate wiring line 25, in the semiconductor portion 27D constituting the TFT 27 to be connected to the pixel electrode 28 adjacent at the lower side of FIG. 5 in the Y-axis direction.

As illustrated in FIG. 6, the first interlayer insulating film 33 and the second interlayer insulating film 34 are interposed between the drain electrode 27C and the semiconductor portion 27D overlapping each other. At a position overlapping at least both the drain electrode 27C and the semiconductor portion 27D in the first interlayer insulating film 33 and the second interlayer insulating film 34, a first contact hole CH1 is provided passing therethrough. The drain electrode 27C and the semiconductor portion 27D are connected to each other through the first contact hole CH1. The first contact hole CH1 is disposed at a position overlapping an end portion of the drain electrode 27C extending along the Y-axis direction on the side opposite to the gate electrode 27A (the lower side in FIG. 5) and an end portion of the portion of the semiconductor portion 27D extending along the Y-axis direction on the side opposite to the gate electrode 27A (the lower side in FIG. 5).

As illustrated in FIG. 6, the first interlayer insulating film 33 is interposed between the source electrode 27B and the semiconductor portion 27D overlapping each other. In the first interlayer insulating film 33, a second contact hole CH2 is provided at a position overlapping at least both the source electrode 27B and the semiconductor portion 27D. The source electrode 27B and the semiconductor portion 27D are connected to each other through the second contact hole CH2.

As illustrated in FIG. 6, the third interlayer insulating film 35 is interposed between the drain electrode 27C and the pixel electrode 28 overlapping each other. In the third interlayer insulating film 35, a third contact hole CH3 is provided at a position overlapping at least both the drain electrode 27C and the pixel electrode 28. The drain electrode 27C and the pixel electrode 28 are connected to each other through the third contact hole CH3. The third contact hole CH3 is disposed at a position overlapping an end portion of the drain electrode 27C extending along the Y-axis direction on the gate electrode 27A side (the upper side in FIG. 5) and an end portion of the pixel electrode 28 extending along the Y-axis direction on the gate electrode 27A side (the upper side in FIG. 5). In the present embodiment, the third contact hole CH3 is disposed to overlap the gate electrode 27A (the gate wiring line 25).

As illustrated in FIGS. 5 and 6, the second insulating film 31 included in the array substrate 21 according to the present embodiment is provided with an opening 31A at a position overlapping at least part of the first contact hole CH1. In the present embodiment, the opening 31A is disposed at a position overlapping both the semiconductor portion 27D and the drain electrode 27C. Specifically, the opening 31A is disposed at a position concentric with the first contact hole CH1 in a plan view. The opening 31A is disposed at a position overlapping an end portion of the portion of the semiconductor portion 27D extending along the Y-axis direction on the side opposite to the gate electrodes 27A (the lower side in FIG. 5). Accordingly, in other words, the opening 31A is disposed at a position overlapping an end portion of the drain electrode 27C extending along the Y-axis direction on the side opposite to the gate electrodes 27A (the lower side in FIG. 5). The opening 31A is provided passing through the second insulating film 31. Thus, a portion of the first insulating film 30 overlapping the opening 31A is exposed to the upper-layer side through the opening 31A. The portion of the semiconductor portion 27D overlapping the opening 31A enters into the opening 31A and comes into contact with the portion of the first insulating film 30 exposed through the opening 31A. A portion of the drain electrode 27C overlapping the opening 31A enters into the opening 31A together with the semiconductor portion 27D, but is not in direct contact with the first insulating film 30.

Here, since the first transparent electrode film F2 constituting the drain electrode 27C contains oxygen, the oxygen may diffuse from the drain electrode 27C to a portion of the semiconductor portion 27D connected to the drain electrode 27C. In this regard, in the present embodiment, the opening 31A is provided in the second insulating film 31 at a position overlapping at least part of the first contact hole CH1, and thus the semiconductor portion 27D can be brought into contact with the first insulating film 30 through the opening 31A. Since the first insulating film 30 contains at least silicon and nitrogen, hydrogen comes to be contained at the time of film formation. Accordingly, the hydrogen that is contained in the first insulating film 30 is directly diffused into the semiconductor portion 27D in contact with the first insulating film 30 through the opening 31A. Due to this, even in a case where the oxygen contained in the drain electrode 27C is diffused into the semiconductor portion 27D, the hydrogen contained in the first insulating film 30 is diffused into the semiconductor portion 27D, so that the resistance of the semiconductor portion 27D is unlikely to increase; as a result, the contact resistance between the semiconductor portion 27D and the drain electrode 27C is unlikely to increase. In particular, the portion of the semiconductor portion 27D in contact with the first insulating film 30 through the opening 31A overlaps at least part of the first contact hole CH1, and therefore the hydrogen can be efficiently diffused into a portion of the semiconductor portion 27D where the oxygen is likely to be diffused (the portion connected to the drain electrode 27C), thereby effectively suppressing an increase in the resistance of the semiconductor portion 27D. As described above, the contact resistance between the semiconductor portion 27D and the drain electrode 27C is kept low, so that an image signal from the source electrode 27B is unlikely to be blunted when the image signal is transmitted to the drain electrode 27C via the channel region of the semiconductor portion 27D at the time of driving the TFT 27. With this, the pixel electrode 28 can be charged to the potential in accordance with the image signal, and the voltage holding rate of the pixel electrode 28 is kept high, so that the display quality in accordance with the image is improved.

In the present embodiment, since the second insulating film 31 layered on the lower-layer side of the semiconductor film F1 contains at least silicon and oxygen, it hardly contains hydrogen at the time of film formation. Accordingly, the diffusion of hydrogen from the second insulating film 31 to the entire semiconductor portion 27D hardly occurs. Likewise, since the gate insulating film 32 and the first interlayer insulating film 33 layered on the upper-layer side of the semiconductor film F1 at least contains silicon and oxygen, they hardly contain hydrogen at the time of film formation. Accordingly, the diffusion of hydrogen from the gate insulating film 32 and the first interlayer insulating film 33 to the entire semiconductor portion 27D hardly occurs.

Moreover, as illustrated in FIG. 6, a recessed portion 30A is provided at a position overlapping the opening 31A in the first insulating film 30 provided in the array substrate 21 according to the present embodiment. The recessed portion 30A communicates with the overlapping opening 31A, and the inner circumferential face thereof is substantially flush with the inner circumferential face of the opening 31A. The recessed portion 30A has a depth dimension smaller than the thickness of the first insulating film 30. Accordingly, the thickness of the first insulating film 30 is locally smaller at the portion where the recessed portion 30A is formed than the thickness of the portion where the recessed portion 30A is not formed. The inner circumferential face and the bottom face of the recessed portion 30A provided in the first insulating film 30 are exposed to the upper-layer side through the opening 31A. The portion of the semiconductor portion 27D overlapping the opening 31A and the recessed portion 30A enters into the opening 31A and the recessed portion 30A, and comes into contact with the inner circumferential face and the bottom face of the recessed portion 30A exposed through the opening 31A in the first insulating film 30. In the manufacture, when the opening 31A is provided in the second insulating film 31, the recessed portion 30A can be provided at a position overlapping the opening 31A in the first insulating film 30. In a case where the opening 31A is provided in the second insulating film 31 in such a manner that the recessed portion 30A is not formed in the first insulating film 30, the reliability of providing the opening 31A in a manner that passes through the second insulating film 31 may be lowered. In that regard, when the opening 31A is provided in the second insulating film 31 in such a manner that the recessed portion 30A is formed in the first insulating film 30, the opening 31A may be highly reliably provided in the manner that passes through the second insulating film 31. With this, the semiconductor portion 27D and the drain electrode 27C are highly reliably brought into contact with the first insulating film 30 through the opening 31A and the recessed portion 30A.

This embodiment has the above-described structure, and a manufacturing method for the liquid crystal panel 11 will be subsequently described. The manufacturing method for the liquid crystal panel 11 includes a counter substrate manufacturing step of manufacturing the counter substrate 20, an array substrate manufacturing step of manufacturing the array substrate 21, and a bonding step of bonding the manufactured counter substrate 20 and array substrate 21 together. Hereinafter, among the above steps, the array substrate manufacturing step (the manufacturing method for the array substrate 21) will be described.

The array substrate manufacturing step at least includes a first step in which the first insulating film 30 and the second insulating film 31 are formed and patterned, a second step in which the semiconductor film F1 is formed and patterned, a third step in which the gate insulating film 32 is formed and patterned, a fourth step in which the first metal film is formed and patterned, a fifth step in which the first interlayer insulating film 33 is formed and patterned, a sixth step in which the second metal film is formed and patterned, a seventh step in which the second interlayer insulating film 34 is formed and patterned, an eighth step in which the first transparent electrode film F2 is formed and patterned, a ninth step in which the third interlayer insulating film 35 is formed and patterned, and a tenth step in which the second transparent electrode film is formed and patterned. Hereinafter, the first step, the second step, the seventh step, and the eighth step will be mainly described in detail.

The term “patterned” described above means that each film is subjected to a process based on a general photolithography method. Specifically, the process, that is, the patterning of a film to be processed is performed by performing the film formation of a photoresist film on the film to be processed, exposing the photoresist film with an exposure device through a photomask having a predetermined opening pattern, and then developing the photoresist film, and performing etching through the developed photoresist film.

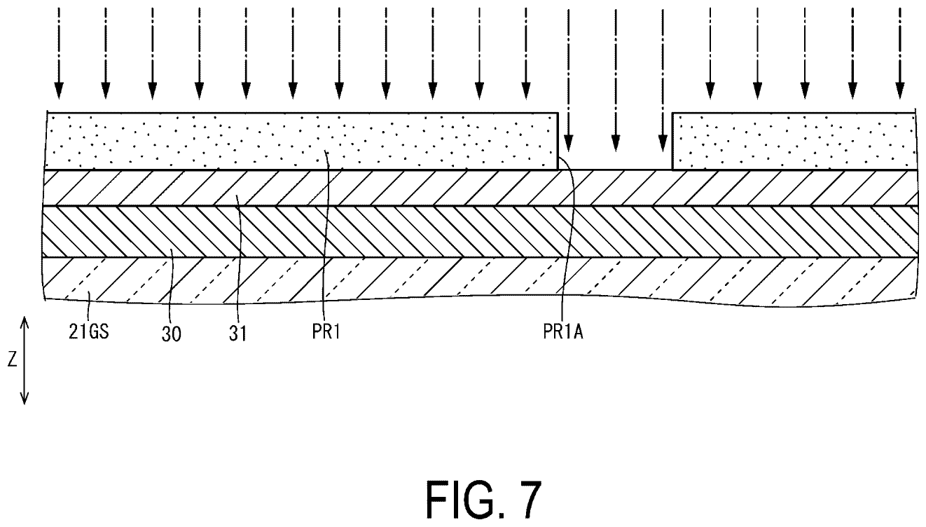

In the first step, the first insulating film 30 is formed on the glass substrate 21GS, and then the second insulating film 31 is formed on the first insulating film 30. Then, a first photoresist film PR1 is formed on the second insulating film 31. The first photoresist film PR1 may be a positive type or a negative type. Thereafter, the first photoresist film PR1 is exposed using an exposure device and a photomask having a predetermined opening pattern (neither the exposure device nor the photomask is illustrated), and then developed. As a result, the first photoresist film PR1 remains on the second insulating film 31 in such a manner that the opening pattern of the photomask is transferred as illustrated in FIG. 7. Specifically, when the first photoresist film PR1 is the positive type, an unexposed portion not overlapping the opening of the photomask remains; when the first photoresist film PR1 is the negative type, an exposed portion overlapping the opening of the photomask remains. The remaining first photoresist film PR1 includes a resist opening PR1A overlapping a position where the opening 31A and the recessed portion 30A are to be formed.

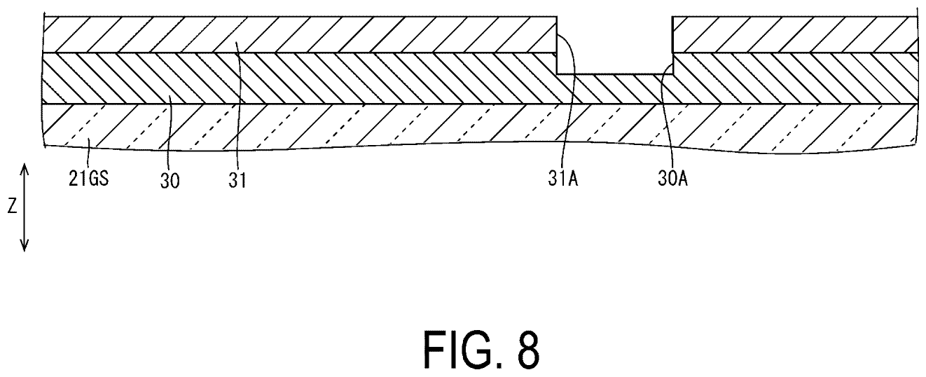

The second insulating film 31 is etched using the first photoresist film PR1 having the above-described configuration as a mask. Then, a portion of the second insulating film 31 overlapping the first photoresist film PR1 remains, and a portion thereof exposed to the resist opening PR1A is selectively removed. By adjusting the etching rate and the etching period of time at this time, as illustrated in FIG. 8, the opening 31A overlapping the resist opening PR1A is provided in a passing-through manner in the second insulating film 31, and further the recessed portion 30A overlapping the resist opening PR1A and the opening 31A is provided in the first insulating film 30 located on the lower-layer side of the second insulating film 31. With this, the opening 31A is provided in the second insulating film 31 passing therethrough, so that the first insulating film 30 is highly reliably exposed through the opening 31A.

In the second step, the semiconductor film F1 is formed on the second insulating film 31, and then a second photoresist film PR2 is formed on the semiconductor film F1. The second photoresist film PR2 may be the positive type or the negative type. Thereafter, the second photoresist film PR2 is exposed using an exposure device and a photomask having a predetermined opening pattern (neither the exposure device nor the photomask is illustrated), and then developed. As a result, the second photoresist film PR2 remains on the semiconductor film F1 in such a manner that the opening pattern of the photomask is transferred as illustrated in FIG. 9. The second photoresist film PR2 remains at a position where the semiconductor portion 27D is to be formed.

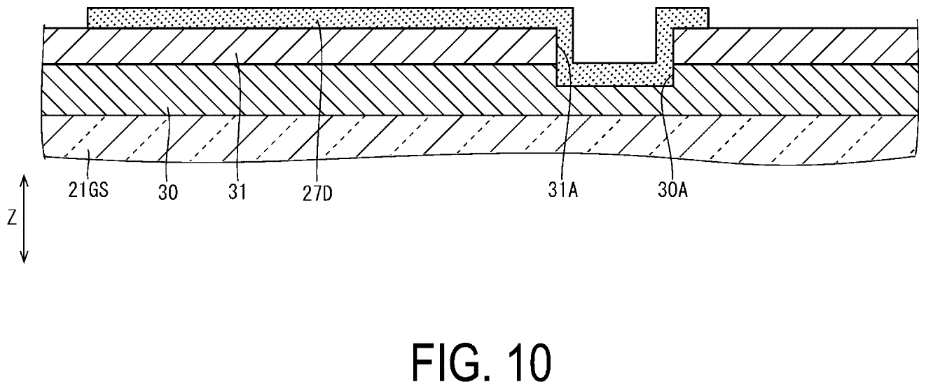

The semiconductor film F1 is etched by using the second photoresist film PR2 having the above-described configuration as a mask. As a result, a portion of the semiconductor film F1 overlapping the second photoresist film PR2 remains, and a portion thereof not overlapping the second photoresist film PR2 is selectively removed. With this, the semiconductor portion 27D is provided as illustrated in FIG. 10. Part of the semiconductor portion 27D enters the interior of the opening 31A of the second insulating film 31 and the interior of the recessed portion 30A of the first insulating film 30, and is in contact with the bottom face and the inner circumferential face of the recessed portion 30A.

When the third step is performed and the gate insulating film 32 is formed and patterned, the gate insulating film 32 is provided in an island shape overlapping the intermediate portion of the semiconductor portion 27D (see FIG. 6). When the fourth step is performed and the first metal film is formed and patterned, the gate electrode 27A and the gate wiring line 25 are provided (see FIG. 6). When the fifth step is performed and the first interlayer insulating film 33 is formed and patterned, the second contact hole CH2 is provided in the first interlayer insulating film 33 (see FIG. 6). When the sixth step is performed and the second metal film is formed and patterned, the source electrode 27B and the source wiring line 26 are provided (see FIG. 6).

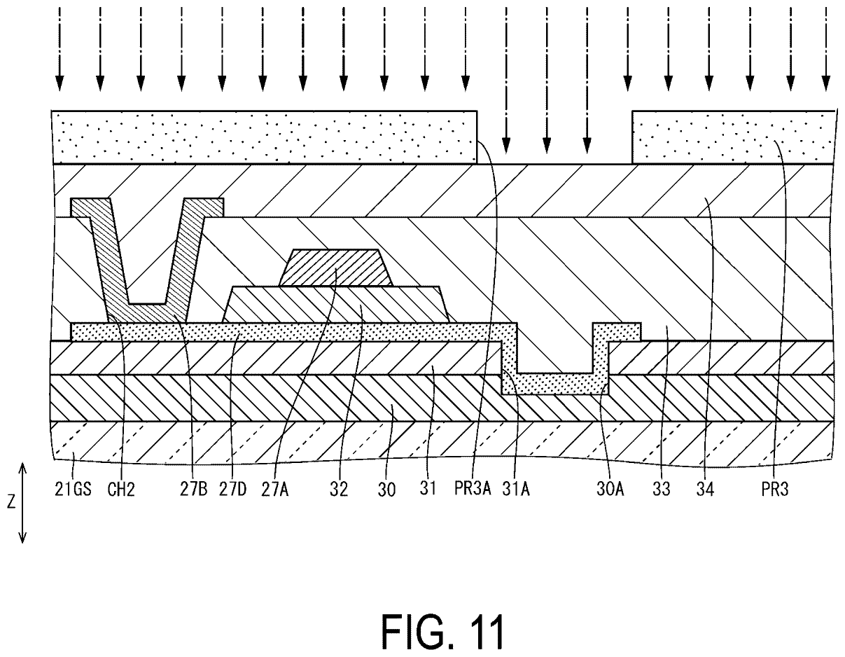

In the seventh step, the second interlayer insulating film 34 is formed on the second metal film, and then a third photoresist film PR3 is formed on the second interlayer insulating film 34. The third photoresist film PR3 may be the positive type or the negative type. Thereafter, the third photoresist film PR3 is exposed using an exposure device and a photomask having a predetermined opening pattern (neither the exposure device nor the photomask is illustrated), and then developed. As a result, the third photoresist film PR3 remains on the second interlayer insulating film 34 in such a manner that the opening pattern of the photomask is transferred as illustrated in FIG. 11. The remaining third photoresist film PR3 includes a resist opening PR3A overlapping a position where the first contact hole CH1 is to be formed.

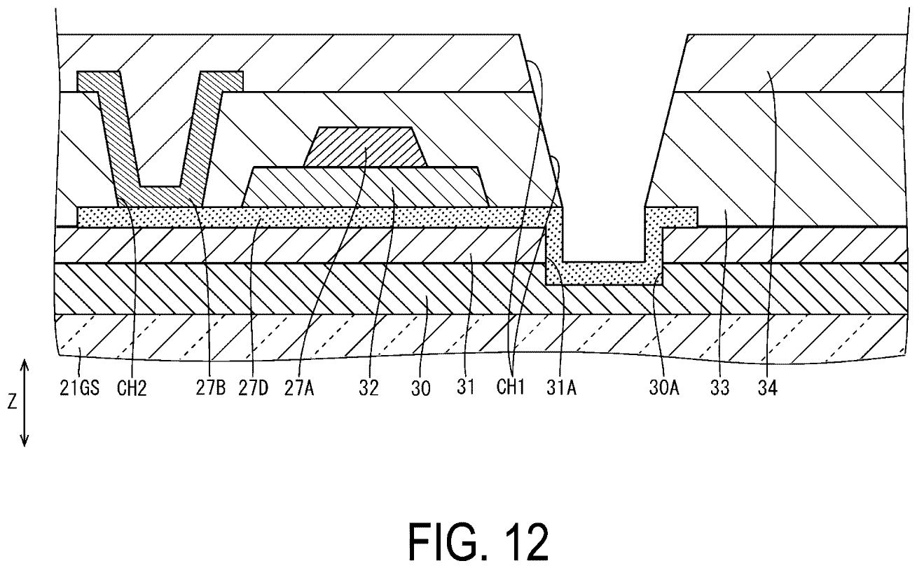

The second interlayer insulating film 34 is etched using the third photoresist film PR3 having the above-described configuration as a mask. Then, a portion of the second interlayer insulating film 34 overlapping the third photoresist film PR3 remains, and a portion thereof exposed to the resist opening PR3A is selectively removed. By adjusting the etching rate and the etching period of time at this time, as illustrated in FIG. 12, part of the first contact hole CH1 overlapping the resist opening PR3A is provided in a passing-through manner in the second interlayer insulating film 34, and further the remaining portion of the first contact hole CH1 overlapping the resist opening PR3A is provided in a passing-through manner in the first interlayer insulating film 33 located on the lower-layer side of the second interlayer insulating film 34. With this, the first contact hole CH1 is provided passing through the first interlayer insulating film 33 and the second interlayer insulating film 34. The first contact hole CH1 is disposed to overlap the opening 31A and the recessed portion 30A.

In the eighth step, the first transparent electrode film F2 is formed on the second interlayer insulating film 34, and then a fourth photoresist film PR4 is formed on the first transparent electrode film F2. The fourth photoresist film PR4 may be a positive type or a negative type. Thereafter, the fourth photoresist film PR4 is exposed using an exposure device and a photomask having a predetermined opening pattern (neither the exposure device nor the photomask is illustrated), and then developed. As a result, the fourth photoresist film PR4 remains on the first transparent electrode film F2 in such a manner that the opening pattern of the photomask is transferred as illustrated in FIG. 13. The fourth photoresist film PR4 remains at a position where the drain electrode 27C is to be formed.

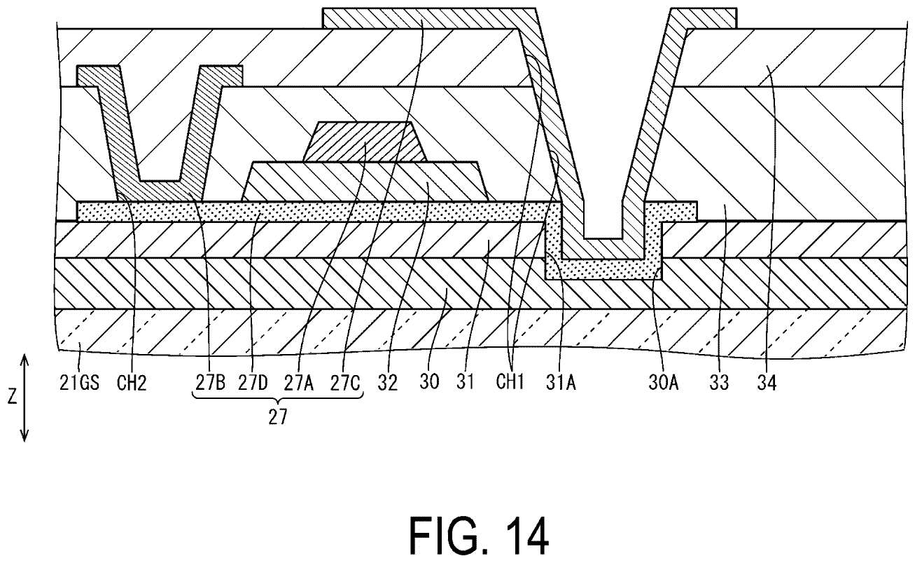

The first transparent electrode film F2 is etched by using the fourth photoresist film PR4 having the above-described configuration as a mask. As a result, a portion of the first transparent electrode film F2 overlapping the fourth photoresist film PR4 remains, and a portion thereof not overlapping the fourth photoresist film PR4 is selectively removed. With this, the drain electrode 27C is provided as illustrated in FIG. 14. The drain electrode 27C is connected to the semiconductor portion 27D through the first contact hole CH1 passing through the first interlayer insulating film 33 and the second interlayer insulating film 34. Since the first contact hole CH1 is disposed overlapping the opening 31A and the recessed portion 30A, the drain electrode 27C is connected to a portion of the semiconductor portion 27D entering the interior of the opening 31A and the recessed portion 30A.

When the ninth step is performed and the third interlayer insulating film 35 is formed and patterned, the third contact hole CH3 is provided in the third interlayer insulating film 35 (see FIG. 6). When the tenth step is performed and the second transparent electrode film is formed and patterned, the pixel electrode 28 is provided (see FIG. 6). The pixel electrode 28 is connected to the drain electrode 27C through the third contact hole CH3 of the third interlayer insulating film 35.

As described above, the array substrate (the semiconductor device) 21 of the present embodiment includes: the first insulating film 30 at least containing silicon and nitrogen; the second insulating film 31 disposed on the upper-layer side of the first insulating film 30 and at least containing silicon and oxygen; the semiconductor portion 27D formed of part of the semiconductor film F1 disposed on the upper-layer side of the second insulating film 31; the first interlayer insulating film (the third insulating film) 33 disposed on the upper-layer side of the semiconductor film F1; and the drain electrode (the first electrode) 27C formed of part of the first transparent electrode film F2 disposed on the upper-layer side relative to the first interlayer insulating film 33, and disposed in such a manner as to at least partially overlap with part of the semiconductor portion 27D, wherein the first contact hole CH1 connecting the semiconductor portion 27D and the drain electrode 27C is provided at a position overlapping at least both the semiconductor portion 27D and the drain electrode 27C in the first interlayer insulating film 33, and the opening 31A is provided at a position overlapping at least part of the first contact hole CH1 in the second insulating film 31.

The semiconductor portion 27D formed of part of the semiconductor film F1 and the drain electrode 27C formed of part of the first transparent electrode film F2 overlap each other and are connected to each other through the first contact hole CH1 of the first interlayer insulating film 33 interposed therebetween. Here, since the first transparent electrode film F2 constituting the drain electrode 27C contains oxygen, the oxygen may diffuse from the drain electrode 27C to a portion of the semiconductor portion 27D connected to the drain electrode 27C. In this regard, the opening 31A is provided in the second insulating film 31 at a position overlapping at least part of the first contact hole CH1, and thus the semiconductor portion 27D and the drain electrode 27C can be brought into contact with the first insulating film 30 through the opening 31A. Since the first insulating film 30 contains at least silicon and nitrogen, hydrogen comes to be contained at the time of film formation. Accordingly, the hydrogen that is contained in the first insulating film 30 is diffused into the semiconductor portion 27D and the drain electrode 27C in contact with the first insulating film 30 through the opening 31A. In the case where the semiconductor portion 27D is in contact with the first insulating film 30, the hydrogen contained in the first insulating film 30 diffuses directly into the semiconductor portion 27D. In the case where the drain electrode 27C is in contact with the first insulating film 30, the hydrogen contained in the first insulating film 30 diffuses indirectly into the semiconductor portion 27D via the drain electrode 27C. Due to this, even in a case where the oxygen contained in the drain electrode 27C is diffused into the semiconductor portion 27D, the hydrogen contained in the first insulating film 30 is diffused into the semiconductor portion 27D, so that the resistance of the semiconductor portion 27D is unlikely to increase; as a result, the contact resistance between the semiconductor portion 27D and the drain electrode 27C is unlikely to increase. In particular, portions of the semiconductor portion 27D and the drain electrode 27C in contact with the first insulating film 30 through the opening 31A overlap at least part of the first contact hole CH1, and therefore the hydrogen can be efficiently diffused into a portion of the semiconductor portion 27D where the oxygen is likely to be diffused, thereby effectively suppressing an increase in the resistance of the semiconductor portion 27D. Since the second insulating film 31 disposed on the lower-layer side of the semiconductor film F1 contains at least silicon and oxygen, it hardly contains hydrogen at the time of film formation. Accordingly, the diffusion of hydrogen from the second insulating film 31 to the entire semiconductor portion 27D hardly occurs.

The recessed portion 30A is provided at a position of the first insulating film 30 overlapping the opening 31A. In the manufacture, when the opening 31A is provided in the second insulating film 31, the recessed portion 30A can be provided at a position overlapping the opening 31A in the first insulating film 30. In a case where the opening 31A is provided in the second insulating film 31 in such a manner that the recessed portion 30A is not formed in the first insulating film 30, the reliability of providing the opening 31A in a manner that passes through the second insulating film 31 may be lowered. In that regard, when the opening 31A is provided in the second insulating film 31 in such a manner that the recessed portion 30A is formed in the first insulating film 30, the opening 31A may be highly reliably provided in the manner that passes through the second insulating film 31. With this, the semiconductor portion 27D and the drain electrode 27C are highly reliably brought into contact with the first insulating film 30 through the opening 31A and the recessed portion 30A.

The opening 31A is disposed at a position overlapping both the semiconductor portion 27D and the drain electrode 27C. The portion of the semiconductor portion 27D connected to the drain electrode 27C through the first contact hole CH1 is in contact with the first insulating film 30 through the opening 31A. Hydrogen is directly diffused from the first insulating film 30 to the portion of the semiconductor portion 27D into which the oxygen from the drain electrode 27C is diffused. This makes it more difficult for the contact resistance between the semiconductor portion 27D and the drain electrode 27C to increase.

There are provided the gate insulating film (fourth insulating film) 32 disposed on the upper-layer side of the semiconductor film F1 and on the lower-layer side relative to the first interlayer insulating film 33, and disposed at a position overlapping with part of the semiconductor portion 27D; the gate electrode (second electrode) 27A formed of part of the first metal film disposed on the upper-layer side of the gate insulating film 32 and on the lower-layer side of the first interlayer insulating film 33, and disposed at a position overlapping with part of the gate insulating film 32 and part of the semiconductor portion 27D; the source electrode (third electrode) 27B formed of part of the second metal film disposed on the upper-layer side of the first interlayer insulating film 33 and on the lower-layer side relative to the first transparent electrode film F2, and disposed at a position overlapping with part of the semiconductor portion 27D; the second interlayer insulating film (fifth insulating film) 34 disposed on the upper-layer side of the second metal film and on the lower-layer side of the first transparent electrode film F2; the third interlayer insulating film (sixth insulating film) 35 disposed on the upper-layer side of the first transparent electrode film F2; and the pixel electrode (fourth electrode) 28 formed of part of the second transparent electrode film disposed on the upper-layer side of the third interlayer insulating film 35, and disposed partially overlapping the drain electrode 27C, wherein the second contact hole CH2 connecting the semiconductor portion 27D and the source electrode 27B is provided at a position in the first interlayer insulating film 33 overlapping both the semiconductor portion 27D and the source electrode 27B, the third contact hole CH3 connecting the drain electrode 27C and the pixel electrode 28 is provided at a position in the third interlayer insulating film 35 overlapping both the drain electrode 27C and the pixel electrode 28, and the first contact hole CH1 is provided passing through the first interlayer insulating film 33 and the second interlayer insulating film 34. When a potential equal to or higher than a predetermined potential is supplied to the gate electrode 27A overlapping with part of the semiconductor portion 27D via the gate insulating film 32, a channel region is generated in a portion of the semiconductor portion 27D overlapping the gate electrode 27A. Then, the drain electrode 27C comes to be at the same potential as the source electrode 27B via the channel region of the semiconductor portion 27D, and thus the pixel electrode 28 also comes to be at the same potential as the source electrode 27B. The semiconductor portion 27D formed of part of the semiconductor film F1 and the source electrode 27B formed of part of the second metal film overlap each other and are connected to each other through the second contact hole CH2 of the first interlayer insulating film 33 interposed therebetween. The drain electrode 27C formed of part of the first transparent electrode film F2 and the pixel electrode 28 formed of part of the second transparent electrode film overlap each other and are connected to each other through the third contact hole CH3 of the third interlayer insulating film 35 interposed therebetween. The semiconductor portion 27D formed of part of the semiconductor film F1 and the drain electrode 27C formed of part of the first transparent electrode film F2 are connected to each other through the first contact hole CH1 passing through the first interlayer insulating film 33 and second interlayer insulating film 34 interposed therebetween. As described above, the pixel electrodes 28 and the semiconductor portion 27D are connected to each other via the drain electrodes 27C. Since the drain electrode 27C overlapping the pixel electrodes 28 is formed of part of the first transparent electrode film F2, the quantity of light passing through the pixel electrode 28 can be increased as compared with a case where the drain electrode 27C is formed of part of a metal film.

The liquid crystal panel (display device) 11 according to the present embodiment includes the array substrate 21 described above and the counter substrate 20 disposed facing the array substrate 21. According to the liquid crystal panel 11 discussed above, the increase in the contact resistance between the semiconductor portion 27D and the drain electrode 27C is suppressed, and thus a signal transmitted between the semiconductor portion 27D and the drain electrode 27C is unlikely to be blunted. With this, preferred display quality may be obtained.

### Second Embodiment

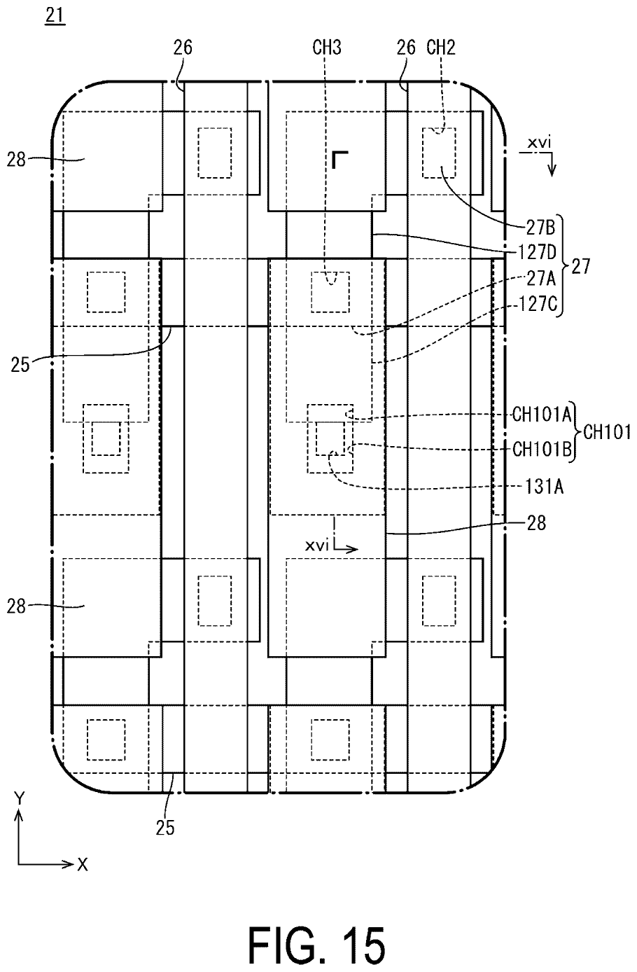

A second embodiment will be described with reference to FIGS. 15 to 20. In the second embodiment, a case in which dispositions of a first contact hole CH101, an opening 131A and a recessed portion 130A, and the like are changed will be described. Further, repetitive descriptions of structures, actions, and effects similar to those of the first embodiment described above will be omitted.

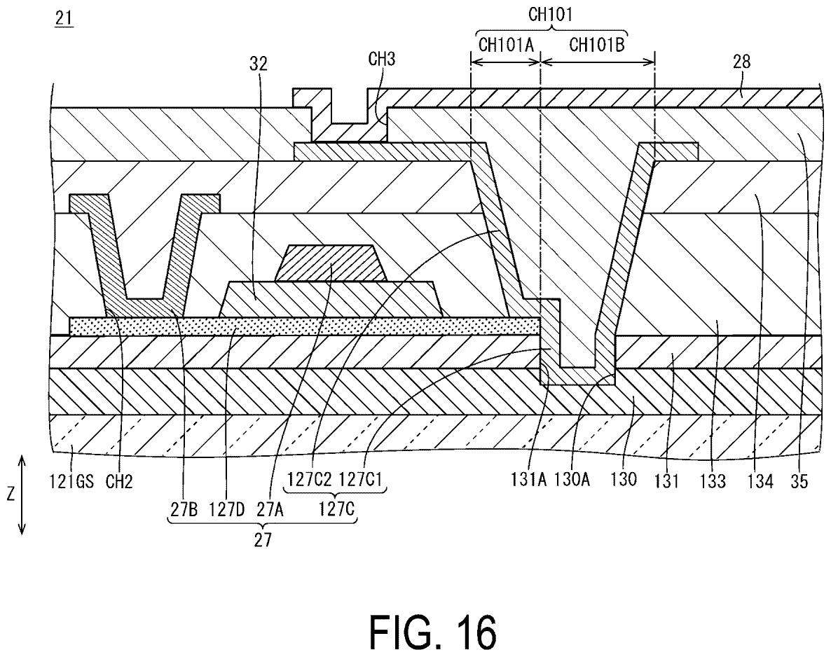

As illustrated in FIGS. 15 and 16, the length dimension (dimension in a Y-axis direction) of a semiconductor portion 127D according to the present embodiment is smaller than that of the first embodiment. With this, a portion of a drain electrode 127C that does not overlap the semiconductor portion 127D is expanded, and this portion is referred to as a non-overlapping portion 127C1. Further, a portion of the drain electrode 127C that overlaps the semiconductor portion 127D is referred to as an overlapping portion 127C2. The non-overlapping portion 127C1 is disposed at a position adjacent to the semiconductor portion 127D at the lower side of FIG. 15 in the Y-axis direction (the right side in FIG. 16). The overlapping portion 127C2 is connected to an end portion of a portion of the semiconductor portion 127D extending along the Y-axis direction through the first contact hole CH101 described below.

Then, as illustrated in FIGS. 15 and 16, the first contact hole CH101 extends along the Y-axis direction, has an elongated rectangular shape in a plan view, and is disposed across the end portion of the portion of the semiconductor portion 127D extending along the Y-axis direction. The first contact hole CH101 is disposed at a position overlapping both the drain electrode 127C and the semiconductor portion 127D and also at a position overlapping the drain electrode 127C and not overlapping the semiconductor portion 127D. Hereinafter, the first contact hole CH101 is divided into a first range CH101A overlapping both the drain electrode 127C and the semiconductor portion 127D, and a second range CH101B overlapping the drain electrode 127C and not overlapping the semiconductor portion 127D. The first range CH101A of the first contact hole CH101 overlaps with the overlapping portion 127C2 of the drain electrode 127C. The second range CH101B of the first contact hole CH101 overlaps with the non-overlapping portion 127C1 of the drain electrode 127C.

As illustrated in FIGS. 15 and 16, a second insulating film 131 is provided such that the opening 131A is disposed at a position overlapping the drain electrode 127C and not overlapping the semiconductor portion 127D. That is, the opening 131A is disposed at the position overlapping the non-overlapping portion 127C1 of the drain electrode 127C, and overlaps with the second range CH101B of the first contact hole CH101. In such a configuration, the semiconductor portion 127D does not enter the interior of the opening 131A. In contrast, the non-overlapping portion 127C1, which is a portion of the drain electrode 127C overlapping the opening 131A, enters into the opening 131A and comes into contact with a portion of a first insulating film 130 exposed through the opening 131A.

As illustrated in FIG. 16, the first insulating film 130 is provided so that the recessed portion 130A is disposed at a position overlapping the opening 131A described above. Accordingly, similarly to the opening 131A, the recessed portion 130A is disposed at a position overlapping the non-overlapping portion 127C1 of the drain electrode 127C, and overlaps with the second range CH101B of the first contact hole CH101. The non-overlapping portion 127C1 of the drain electrode 127C, which is a portion overlapping the opening 131A and the recessed portion 130A, enters into the opening 131A and the recessed portion 130A, and comes into contact with an inner circumferential face and a bottom face of the recessed portion 130A exposed through the opening 131A in the first insulating film 130. Accordingly, hydrogen contained in the first insulating film 130 diffuses indirectly into the semiconductor portion 127D via the drain electrode 127C. Due to this, even in a case where oxygen contained in the drain electrode 127C is diffused into the semiconductor portion 127D, the hydrogen contained in the first insulating film 130 is diffused into the semiconductor portion 127D via the drain electrode 127C, so that the resistance of the semiconductor portion 127D is unlikely to increase; as a result, the contact resistance between the semiconductor portion 127D and the drain electrode 127C is unlikely to increase. In the manufacture, when the first contact hole CH101 is provided in a first interlayer insulating film 133 and a second interlayer insulating film 134, the opening 131A can be provided at a position in the second insulating film 131 not overlapping the semiconductor portion 127D. In the case where the opening 31A is disposed at a position overlapping the semiconductor portion 27D as in the first embodiment described above, the opening 31A needs to be provided in the second insulating film 31 during the formation of the semiconductor film F1 after the formation of the second insulating film 31. In contrast, in the present embodiment, the first contact hole CH101 and the opening 131A can be provided in one step, and therefore the tact time can be shortened, or the like.

The present embodiment has the above-described structure, and subsequently, an array substrate manufacturing step included in the manufacturing method for the liquid crystal panel 11 will be mainly described. Hereinafter, the first step, the seventh step, and the eighth step will be described in detail. The second to sixth steps, the ninth step, and the tenth step are as described in the first embodiment.

In the first step, the first insulating film 130 is formed on a glass substrate 121GS, and then the second insulating film 131 is formed on the first insulating film 130. However, unlike the first embodiment, none of the first insulating film 130 and the second insulating film 131 are patterned (see FIG. 16). Accordingly, in the first step, the formation of a photoresist film on the second insulating film 131 or the exposure and development of the photoresist film is unnecessary. Because of this, various devices such as a photomask are not needed, and the tact time can be shortened.

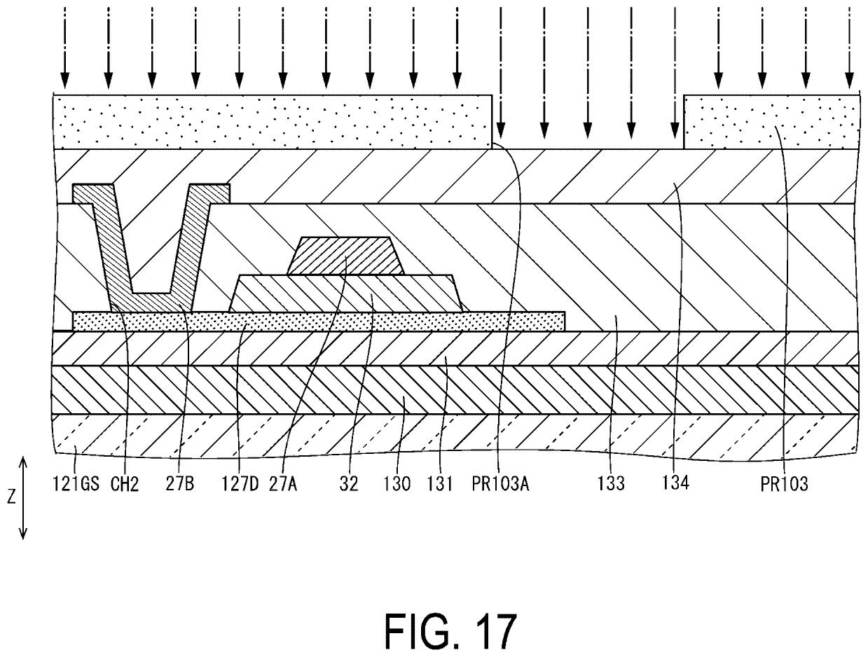

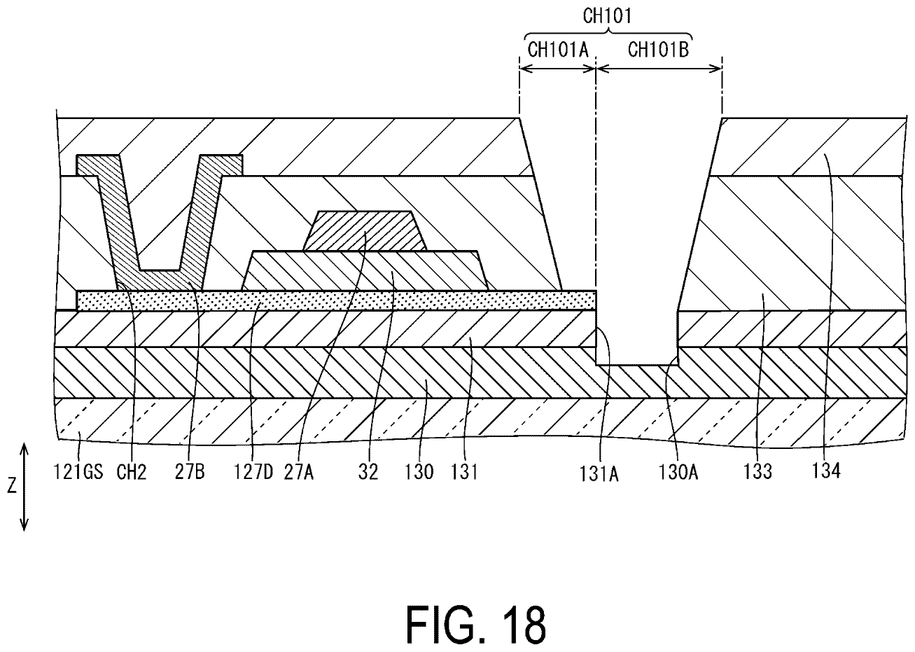

In the seventh step, when a third photoresist film PR103 formed on the second interlayer insulating film 134 is exposed and developed, the third photoresist film PR103 is patterned as illustrated in FIG. 17. The third photoresist film PR103 remaining on the second interlayer insulating film 134 includes a resist opening PR103A overlapping a position where the first contact hole CH101 is to be formed. By etching the second interlayer insulating film 134 and the first interlayer insulating film 133 using the third photoresist film PR103 having the above configuration as a mask, the first contact hole CH101 passing through the first interlayer insulating film 133 and the second interlayer insulating film 134 is provided. By adjusting the etching rate and the etching period of time at this time, as illustrated in FIG. 18, the opening 131A communicating with the second range CH101B of the first contact hole CH101 is provide in the second insulating film 131, and further the recessed portion 130A communicating with the opening 131A is provided in the first insulating film 130 located on the lower-layer side of the second insulating film 131. The portions of the first insulating film 130 and the second insulating film 131 overlapping the first range CH101A of the first contact hole CH101 are covered with the semiconductor portion 127D, and are therefore inhibited from being etched. With this, the first contact hole CH101 is provided in the first interlayer insulating film 133 and the second interlayer insulating film 134; in addition, the opening 131A is provided in the second insulating film 131, and further the recessed portion 130A is provided in the first insulating film 130. As described above, the first contact hole CH101, the opening 131A, and the recessed portion 130A are collectively provided in one step, which is preferable for the improvement of production efficiency.

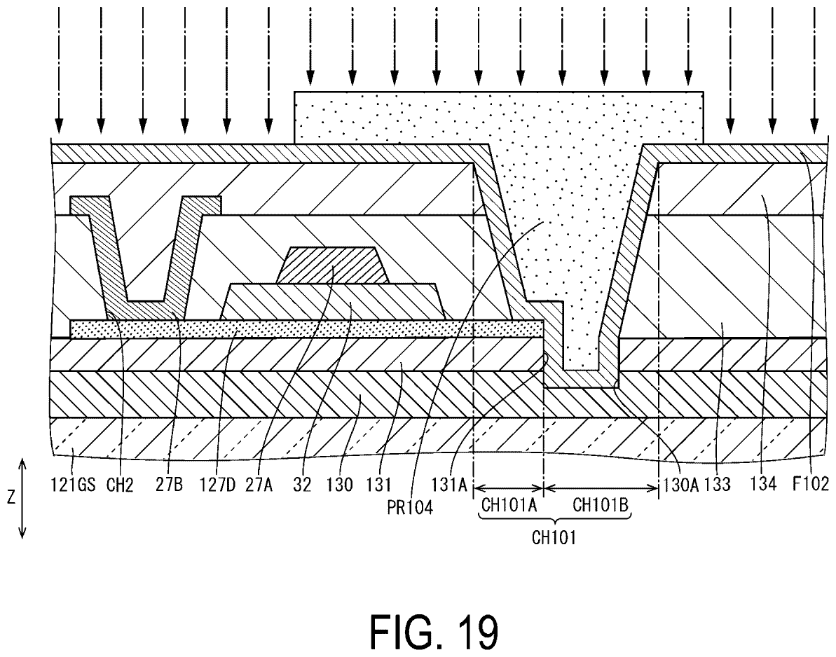

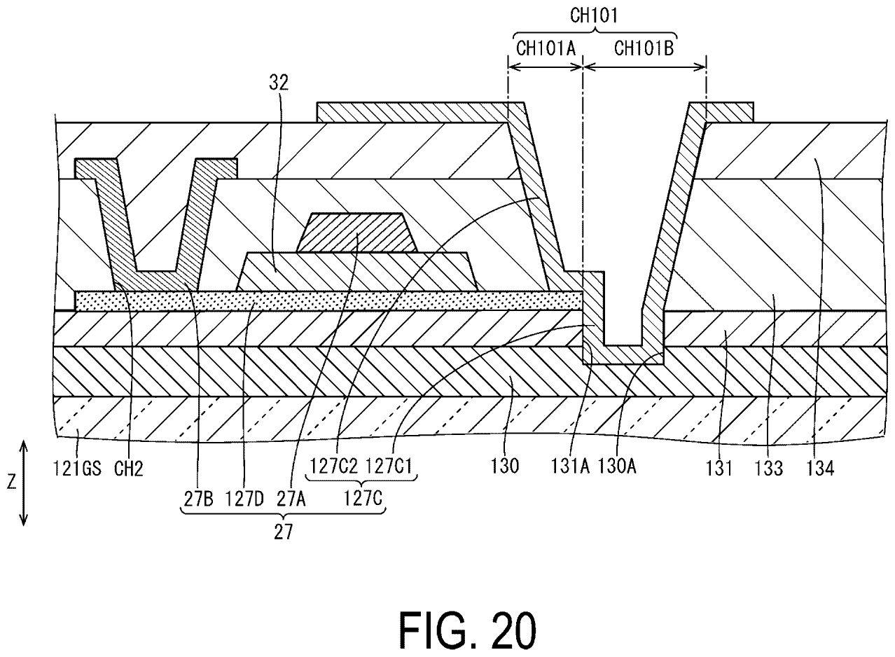

In the eighth step, when a fourth photoresist film PR104 formed on a first transparent electrode film F102 is exposed and developed, the fourth photoresist film PR104 is patterned as illustrated in FIG. 19. The fourth photoresist film PR104 remaining on the first transparent electrode film F102 is disposed at a position where the drain electrode 127C is to be formed. By etching the first transparent electrode film F102 using the fourth photoresist film PR104 having the above-described configuration as a mask, the drain electrode 127C is provided as illustrated in FIG. 20. The overlapping portion 127C2 of the drain electrode 127C is connected to the semiconductor portion 127D through the first range CH101A of the first contact hole CH101 passing through the first interlayer insulating film 133 and the second interlayer insulating film 134. On the other hand, the non-overlapping portion 127C1 of the drain electrode 127C enters the interior of the opening 131A and the recessed portion 130A through the second range CH101B of the first contact hole CH101, and comes into contact with the bottom face and the inner circumferential face of the recessed portion 130A in the first insulating film 130.

As described above, according to the present embodiment, the drain electrode 127C has a portion not overlapping the semiconductor portion 127D, the first contact hole CH101 is also disposed at a position overlapping the drain electrode 127C and not overlapping the semiconductor portion 127D, and the opening 131A is disposed at a position overlapping the drain electrode 127C and not overlapping the semiconductor portion 127D. The portion of the drain electrode 127C not overlapping the semiconductor portion 127D is in contact with the first insulating film 130 through the first contact hole CH101 and the opening 131A. Accordingly, the hydrogen contained in the first insulating film 130 diffuses indirectly into the semiconductor portion 127D via the drain electrode 127C. In the manufacture, when the first contact hole CH101 is provided in the first interlayer insulating film 133, the opening 131A can be provided at a position in the second insulating film 131 not overlapping the semiconductor portion 127D. In a case where the opening 31A is disposed at a position overlapping the semiconductor portion 27D, the opening 31A needs to be provided in the second insulating film 31 during the formation of the semiconductor film F1 after the formation of the second insulating film 31. As compared to the above case, the first contact hole CH101 and the opening 131A can be provided in one step, and therefore the tact time can be shortened, or the like.

### Other Embodiments

The techniques disclosed herein are not limited to the embodiments described above and illustrated in the drawings, and the following embodiments, for example, are also included within the technical scope.
(1) In the configuration described in the second embodiment, the opening 131A and the recessed portion 130A may be provided to expand to a range overlapping the semiconductor portion 127D. In this case, the semiconductor portion 127D and the drain electrode 127C are respectively in direct contact with the first insulating film 130. The opening 131A and the recessed portion 130A are provided in the first step as described in the first embodiment.
(2) The formation ranges of the recessed portions 30A, 130A in a plan view may be narrower than those of the openings 31A, 131A in a plan view.
(3) The first insulating films 30, 130 may be configured not to include the recessed portions 30A, 130A.
(4) The specific materials used for the first insulating films 30, 130 and the second insulating films 31, 131 can be changed as appropriate to other materials than those described above. Further, the specific materials used for the gate insulating film 32, the first interlayer insulating films 33, 133, the second interlayer insulating film 34, 134, and the third interlayer insulating film 35 can also be changed as appropriate.
(5) The formation ranges of the first contact holes CH1, CH101 in a plan view can be changed as appropriate to ranges other than those illustrated in the drawings.
(6) The disposition of the third contact hole CH3 can be changed as appropriate to other dispositions than those illustrated in the drawings (for example, to a position not overlapping the gate electrode 27A).
(7) The semiconductor film F1 may be an amorphous silicon thin film or a polycrystalline silicon thin film.
(8) The TFT 27 is not limited to a top gate type, and may be a bottom gate type or a double gate type.
(9) A source driver may be attached to the array substrates 21 instead of the second circuit portion 14B.
(10) A source driver may be attached to the flexible substrate 13 instead of the second circuit portion 14B.
(11) A gate driver may be attached to the array substrates 21 instead of the first circuit portion 14A.
(12) The liquid crystal panel 11 may be a reflective type or a semi-transmissive type, in addition to a transmissive type. When the liquid crystal panel 11 is the reflective type, the backlight device 12 may be omitted.
(13) In addition to the head-mounted display 10HMD, the disclosure can be applied to, for example, a head-up display or a projector as a device that enlarges and displays an image displayed on the liquid crystal panel 11 using a lens or the like. The disclosure can be also applied to a display device that does not have an enlarged display function (a television receiver, a tablet terminal, a smartphone, or the like).

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. A semiconductor device comprising:
a first insulating film at least including silicon and nitrogen;
a second insulating film disposed on an upper-layer side of the first insulating film and at least including silicon and oxygen;
a semiconductor portion formed of part of a semiconductor film disposed on the upper-layer side of the second insulating film;
a third insulating film disposed on the upper-layer side of the semiconductor film; and
a first electrode formed of part of a first transparent electrode film disposed on the upper-layer side relative to the third insulating film, and disposed at least partially overlapping with part of the semiconductor portion,
wherein a first contact hole that connects the semiconductor portion and the first electrode is provided at a position overlapping at least both the semiconductor portion and the first electrode in the third insulating film, and
an opening is provided at a position overlapping at least part of the first contact hole in the second insulating film.

2. The semiconductor device according to claim 1,
wherein a recessed portion is provided in the first insulating film at a position overlapping the opening.

3. The semiconductor device according to claim 1,
wherein the opening is disposed at a position overlapping both the semiconductor portion and the first electrode.

4. The semiconductor device according to claim 1,
wherein the first electrode includes a portion that does not overlap the semiconductor portion,
the first contact hole is also disposed at a position that overlaps the first electrode and does not overlap the semiconductor portion, and
the opening is disposed at a position that overlaps the first electrode and does not overlap the semiconductor portion.

5. The semiconductor device according to claim 1, further comprising:
a fourth insulating film disposed on the upper-layer side of the semiconductor film and on a lower-layer side relative to the third insulating film, and disposed at a position overlapping with part of the semiconductor portion;
a second electrode formed of part of a first metal film disposed on the upper-layer side of the fourth insulating film and on the lower-layer side of the third insulating film, and disposed at a position overlapping with part of the fourth insulating film and part of the semiconductor portion;
a third electrode formed of part of a second metal film disposed on the upper-layer side of the third insulating film and on the lower-layer side relative to the first transparent electrode film, and disposed at a position overlapping with part of the semiconductor portion;
a fifth insulating film disposed on the upper-layer side of the second metal film and on the lower-layer side of the first transparent electrode film;
a sixth insulating film disposed on the upper-layer side of the first transparent electrode film; and
a fourth electrode formed of part of a second transparent electrode film disposed on the upper-layer side of the sixth insulating film, and disposed partially overlapping the first electrode,
wherein a second contact hole connecting the semiconductor portion and the third electrode is provided at a position in the third insulating film overlapping both the semiconductor portion and the third electrode,
a third contact hole connecting the first electrode and the fourth electrode is provided at a position in the sixth insulating film overlapping both the first electrode and the fourth electrode, and
the first contact hole is provided passing through the third insulating film and the fifth insulating film.

6. A display device comprising:
the semiconductor device according to claim 1; and
a counter substrate that is disposed facing the semiconductor device.
